(19) United States
(12) Patent Application Publication
(10) Pub. No.: US 2025/0386613 A1
(43) Pub. Date: Dec. 18, 2025

(54) IMAGE SENSING DEVICE

(71) Applicant: SK hynix Inc., Icheon-si (KR)

(72) Inventor: Ji Suk PARK, Icheon-si (KR)

(21) Appl. No.: 19/185,016

(22) Filed: Apr. 21, 2025

(30) Foreign Application Priority Data
Jun. 13, 2024 (KR) 10-2024-0076792

(51) Int. Cl. H10F 39/00

(52) U.S. Cl. CPC H10F 39/807

(57) ABSTRACT

The image sensing device includes a semiconductor substrate including a first surface and a second surface facing or opposite to the first surface, photoelectric conversion regions supported by the semiconductor substrate and configured to generate photocharges in response to incident light received through the first surface, and a pixel isolation structure disposed between adjacent photoelectric conversion regions in the semiconductor substrate and configured to have a conductive material. The pixel isolation structure includes a first deep trench isolation (DTI) electrode extending from the second surface toward the first surface, and a second DTI electrode extending from the first surface toward the second surface and disposed apart from the first deep trench isolation (DTI) electrode to define a space for an air layer including air.

### CROSS-REFERENCE TO RELATED APPLICATION

This patent document claims the priority and benefits of Korean patent application No. 10-2024-0076792, filed on Jun. 13, 2024, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

### SUMMARY

Various embodiments of the disclosed technology relate to an image sensing device capable of improving light efficiency while improving dark current characteristics.

In accordance with an embodiment of the disclosed technology, an image sensing device may include a semiconductor substrate including a first surface and a second surface facing or opposite to the first surface, photoelectric conversion regions supported by the semiconductor substrate and configured to generate photocharges in response to incident light received through the first surface; and a pixel isolation structure disposed between adjacent photoelectric conversion regions in the semiconductor substrate and configured to have a conductive material. The pixel isolation structure may include: a first deep trench isolation (DTI) electrode extending from the second surface toward the first surface; and a second DTI electrode extending from the first surface toward the second surface and disposed apart from the first deep trench isolation (DTI) electrode to define a space for an air layer including air.

In accordance with another embodiment of the disclosed technology, an image sensing device may include a semiconductor substrate including photoelectric conversion regions configured to generate photocharges in response to incident light; and a pixel isolation structure disposed between the photoelectric conversion regions within the semiconductor substrate. The pixel isolation structure may include: a first deep trench isolation (DTI); and a second deep trench isolation (DTI) disposed to be isolated from the first DTI by an air layer including air.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example structure of a portion of a pixel array shown in FIG. 1 based on some implementations of the disclosed technology.

FIG. 3 is a cross-sectional view illustrating an example of the pixel array taken along the line X-X′ shown in FIG. 2 based on some implementations of the disclosed technology.

FIGS. 4A to 4E are cross-sectional views illustrating examples of methods for forming a pixel isolation structure of FIG. 3 based on some implementations of the disclosed technology.

FIGS. 5A and 5B are cross-sectional views illustrating examples of the pixel array taken along the line X-X′ shown in FIG. 2 based on some other implementations of the disclosed technology.

FIG. 6 is a cross-sectional view illustrating an example of the pixel array taken along the line X-X′ shown in FIG. 2 based on some other implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device that can improve light efficiency while improving dark current characteristics. In recognition of the issues above, the disclosed technology provides various implementations of the image sensing device that can improve light efficiency while improving dark current characteristics.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

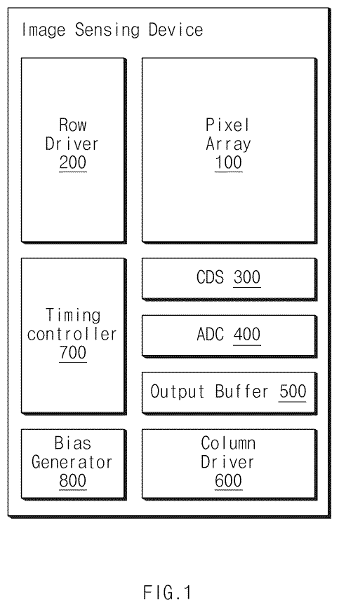

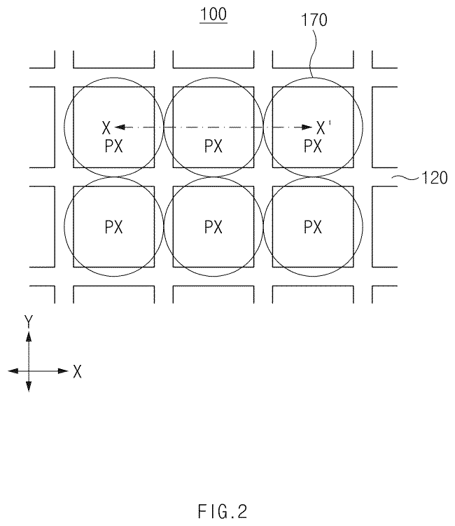

FIG. 1 is a block diagram illustrating an example of an image sensing device based on some implementations of the disclosed technology. FIG. 2 is a plan view illustrating an example structure of a portion of a pixel array shown in FIG. 1 based on some implementations of the disclosed technology.

Referring to FIGS. 1 and 2, the image sensing device may include a pixel array 100, a row driver 200, a correlated double sampler (CDS) 300, an analog-to-digital converter (ADC) 400, an output buffer 500, a column driver 600, a timing controller 700, and a bias generator 800. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

Referring to FIG. 2, the pixel array 100 may include a plurality of unit pixels (PXs) consecutively arranged not only in a first direction (e.g., an X-axis direction), but also in a second direction (e.g., a Y-axis direction) perpendicular to the first direction. The plurality of unit pixels (PXs) may convert incident light received through a lens layer 170 to generate an electrical signal (pixel signal) for image generation or distance measurement. One or more pixel isolation structures 120 extending to cross each other in the first direction and the second direction may be formed between the unit pixels (PXs). The pixel isolation structure 120 may include a trench isolation structure in which a conductive electrode (DTI electrode) is buried in a trench formed by etching a semiconductor substrate. The pixel array 100 may receive a bias voltage from the bias generator 800.

The row driver 200 may operate the unit pixels based on control signals provided by controller circuitry such as the timing controller 700.

The correlated double sampler (CDS) 300 may remove undesired offset values of the unit pixels using correlated double sampling.

The analog-to-digital converter (ADC) 400 may convert analog CDS signals received from the CDS 300 into digital signals.

The output buffer 500 may temporarily store column-based image data provided from the ADC 400 based on control signals of the timing controller 700.

The column driver 600 may select a column of the output buffer 500 upon receiving a control signal from the timing controller 700, and sequentially output the image data, which are temporarily stored in the selected column of the output buffer 500.

The timing controller 700 may generate signals for controlling operations of at least one of the row driver 200, the ADC 400, the output buffer 500, the column driver 600, or the bias generator 800.

The bias generator 800 may generate a bias voltage (Vb) and supply the bias voltage (Vb) to the pixel array 100 to suppress dark current generated in the unit pixels (PXs) of the pixel array 100. For example, the bias generator 800 may generate a negative voltage, and may supply the negative voltage to the pixel isolation structure 120.

The bias voltage (Vb) may be determined during a wafer probe test of the image sensing device and stored in a storage, for example, a one-time programmable (OTP) memory. For example, the bias voltage (Vb) may be experimentally determined as a value that can maximize the dark current suppression effect while minimizing unnecessary power consumption without deteriorating performance of the image sensing device. In some implementations, the bias generator 800 may generate a plurality of bias voltages (Vb) and may supply the plurality of bias voltages (Vb) to the pixel isolation structure 120. For example, the plurality of bias voltages (Vb) may correspond to a plurality of operation modes of the image sensing device, respectively. Since a dark current occurring in a low-illuminance environment and a dark current occurring in a high-illuminance environment may be different from each other, the bias voltage provided by the bias generator 800 to effectively suppress the dark current in each environment may vary depending on the operation mode. In addition, when different types of Deep Trench Isolation (DTI) electrodes are formed within the pixel isolation structure 120, the bias voltage (Vb) may vary depending on the DTI electrode. In the example, the bias voltage is a negative voltage. However, other implementations are also possible. For example, the bias voltage may not be limited to the negative voltage.

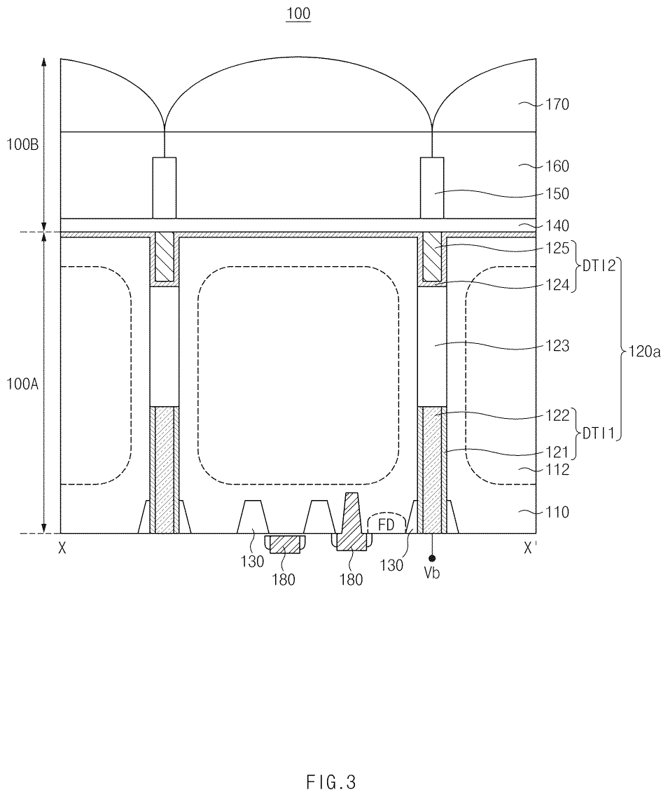

FIG. 3 is a cross-sectional view illustrating an example of the pixel array 100 taken along the line X-X′ shown in FIG. 2 based on some implementations of the disclosed technology.

Referring to FIG. 3, the pixel array 100 may include a substrate region 100A and a light incident region 100B.

The substrate region 100A may include a substrate 110, a pixel isolation structure 120a, and a device isolation structure 130.

The substrate 110 may include a semiconductor substrate formed of or including a semiconductor material. For example, the substrate 110 may be a P-type bulk substrate, or may be a substrate formed by growing a P-type epitaxial layer on the P-type bulk substrate.

The substrate 110 may include a first surface (i.e., a back surface) and a second surface (i.e., a front surface) facing or opposite to the first surface. At this time, the first surface may be a surface upon which light is incident, and the second surface may be a surface upon which the pixel transistors 180 for reading out the pixel signals are formed. In the example, the image sensing device may have a back side illuminance (BSI) structure.

The substrate 110 may include photoelectric conversion regions 112 that convert incident light to generate photocharges. The photoelectric conversion regions 112 may include N-type impurities. The photoelectric conversion regions 112 may be formed through an ion implantation process that implants N-type impurities into the substrate 110. Each photoelectric conversion region 112 may be arranged to occupy as large a region as possible to increase a fill factor indicating light reception (Rx) efficiency. One photoelectric conversion region 112 may be formed for each unit pixel (PX). The photoelectric conversion regions 112 may be isolated by a pixel isolation structure 120a.

In some implementations, the unit pixel (PX) may be defined as a region isolated by the pixel isolation structure 120a within the substrate 110.

The pixel isolation structure 120a may be formed between adjacent unit pixels (PXs) within the substrate 110 to isolate the unit pixels (PXs) from each other.

In addition, the pixel isolation structure 120a may prevent optical crosstalk between adjacent pixels (PXs) to improve the imaging operation.

When viewed in a plane as shown in FIG. 2, the pixel isolation structure 120a may be formed in a shape in which a plurality of lines extending in a first direction and a plurality of other lines extending in a second direction are interconnected to cross each other between the unit pixels (PXs).

The pixel isolation structure 120a may include a trench-type isolation structure formed by etching the substrate 110. For example, the pixel isolation structure 120a may be formed in a frontside deep trench isolation (FDTI) shape in which the substrate 110 is etched from the second surface of the substrate 110 so that the substrate 110 can be penetrated by the FDTI shape.

This pixel isolation structure 120a may include a first DTI (DTI1), an air layer 123, and a second DTI (DTI2).

The first DTI (DTI1) may include a first DTI insulation layer 121 and a first DTI electrode 122.

The first DTI insulation layer 121 may be formed between the substrate 110 and the first DTI electrode 122. For example, the first DTI insulation layer 121 may be formed within the substrate 110 to surround a side surface of the first DTI electrode 122. The first DTI insulation layer 121 may include an insulation layer such as a silicon oxide layer (SiO₂), a silicon nitride layer (SiN), or others.

The first DTI electrode 122 may be formed within the substrate 110 to extend a predetermined length from the second surface of the substrate 110 to the first surface. In some implementations, the first DTI electrode 122 may include at least one of a metal, polysilicon, or doped polysilicon as a conductive material. However, the first DTI electrode 122 may include other materials without being limited thereto.

The first DTI electrode 122 may be formed so that regions extending in the first direction and regions extending in the second direction cross each other to be connected to each other as a whole. The first DTI electrode 122 may receive the bias voltage (Vb) from the bias generator 800. For example, the first DTI electrode 122 may receive the bias voltage (Vb) from the bias generator 800 through a contact and a conductive line formed on the second surface of the substrate 110.

An air layer 123 may be formed between the first DTI (DTI1) and the second DTI (DTI2) and within the substrate 110. The air layer 123 may reflect light within the substrate 110, and may allow the reflected light to flow back into the photoelectric conversion region 112 of the corresponding pixel (PX).

The second DTI (DTI2) may be spaced apart from the first DTI (DTI1) along a direction perpendicular to the surface of the substrate and the air layer 123 is disposed between the first DTI (DTI1) and the second DTI (DTI2) along the direction. The second DTI (DTI2) may be disposed to be isolated from the first DTI (DTI1) by the air layer 123 interposed therebetween. The second DTI (DTI2) may include a second DTI insulation layer 124 and a second DTI electrode 125.

The second DTI insulation layer 124 may be formed between the substrate 110 and the second DTI electrode 125 and between the air layer 123 and the second DTI electrode 125. For example, the second DTI insulation layer 124 may be formed to surround a bottom surface and a side surface of the second DTI electrode 125. In addition, the second DTI insulation layer 124 may be formed to extend over the first surface of the substrate 110 so as to cover the first surface of the substrate 110.

The second DTI insulation layer 124 may include a high-K material including negative fixed charges. For example, the second DTI insulation layer 124 may include at least one of Al₂O₃ or HfO₂. The second DTI insulation layer 124 may include a monolayer structure formed of or including either Al₂O₃ or HfO₂, or may include a multilayer structure formed by stacking Al₂O₃ and HfO₂. Alternatively, the second DTI insulation layer 124 may include an ultra-low temperature oxidation (ULTO) layer.

The second DTI electrode 125 may be formed to extend a predetermined length from the first surface of the substrate 110 to the second surface of the substrate 110. The second DTI electrode 125 may be formed of or include a conductive material, and may include at least one of a metal, polysilicon, or polysilicon doped with impurities. However, the second DTI electrode 125 may include other materials without being limited thereto. For example, the second DTI electrode 125 may include a conductive material having a higher conductivity than the first DTI electrode 122.

The second DTI electrode 125 may be formed so that regions extending in the first direction and regions extending in the second direction cross each other to be connected to each other as a whole. The second DTI electrode 125 may receive the bias voltage (Vb) from the bias generator 800. For example, the second DTI electrode 125 may be formed to extend to a peripheral region of the pixel array 100 and may be connected to a through silicon via (TSV), and may receive the bias voltage (Vb) from the bias generator 800 through the through silicon via (TSV).

The first DTI electrode 122 and the second DTI electrode 125 may include different conductive materials and may have different lengths (lengths extended in the vertical direction of the semiconductor substrate). For example, the first DTI electrode 122 may include doped polysilicon, and the second DTI electrode 125 may include a metal. In some implementations, the second DTI electrode 125 may be formed to have a shorter length than the first DTI electrode 122.

The first DTI electrode 122 and the second DTI electrode 125 may receive different magnitudes of negative voltages from the bias generator 800. For example, a shorter DTI electrode having a shorter length from among the first DTI electrode 122 and the second DTI electrode 125 may receive a lower negative voltage than a longer DTI electrode, and may include an electrode material having a higher conductivity than the longer DTI electrode. Although FIG. 3 illustrates an example case in which the first DTI electrode 122 is formed to have a longer length than the second DTI electrode 125, it is the example only. In other implementations, the first DTI electrode 122 may be formed to have a shorter length than that the second DTI electrode 125.

As in the present embodiment, when the pixel isolation structure is formed in a trench shape formed by etching the semiconductor substrate, a dangling bond may occur at the interface of the trench, which may generate excess charges (excess electrons) as a dark source. The excess charges may cause dark current and deteriorate the operating characteristics of the image sensing device. In order to improve the dark current characteristic, the pixel isolation structure may be formed entirely of a conductive material and a bias voltage may be applied to the conductive material.

However, when the pixel isolation structure is formed entirely of a conductive material, the amount of light converted into electricity by the photoelectric conversion region 112 may be reduced because the conductive material absorbs light. In other words, the quantum efficiency (QE) (light efficiency) of the image sensing device may be reduced.

In some implementations, in order to improve the light efficiency (quantum efficiency QE) while improving the dark current characteristics, a conductive material is formed within the pixel isolation structure 120a and the bias voltage (Vb) is applied to the conductive material, and the air layer 123 may be partially formed only in the region where the incident light collides most frequently with the pixel isolation structure 120a. For example, in the present embodiment, the air layer 123 may be partially formed in the central portion of the pixel isolation structure 120a between the DTI electrodes 122 and 125, and DTI electrodes 122 and 125 may be formed above and below the air layer 123.

In some implementations, the second DTI electrode 125 having a short length may include a conductive material having a higher conductivity than the first DTI electrode 122. In addition, in order to enhance the dark current characteristics by strengthening the field effect, the second insulation layer 124 may be formed of or include a high-K material including negative fixed charges. In addition, the pixel isolation structure 120a including the air layer 123 may have lower dark current characteristics compared to the pixel isolation structure in which the conductive material is formed entirely without the air layer 123. Therefore, a negative voltage applied to the first DTI electrode 122 and the second DTI electrode 125 of the pixel isolation structure 120a including the air layer 123 may be lower than the negative voltage applied to the pixel isolation structure in which the conductive material is formed entirely without the air layer 123.

The device isolation structure 130 may be formed over the second surface of the substrate 110 within the pixel (PX), and may define an active region in which the pixel transistors 180 are formed. The device isolation structure 130 may include a trench-type isolation structure in which an insulation material is buried in a trench etched to a predetermined depth from the second surface of the substrate 110. For example, the device isolation structure 130 may include a shallow trench isolation (STI) structure. In a boundary region between the unit pixels (PX), the device isolation structure 130 may be penetrated by the pixel isolation structure 120a.

The light incident region 100B may be formed over the first surface of the substrate 110 and may allow incident light to be introduced into the substrate region 100A. The light incident region 100B may include at least one of an anti-reflection layer 140, a grid structure 150, a color filter layer 160, or a lens layer 170.

The anti-reflection layer 140 may allow light that has penetrated the lens layer 170 and the color filter layer 160 to be efficiently incident into the substrate 110 without being reflected from the first surface of the substrate 110. For example, the anti-reflection layer 140 may have a lower refractive index than each of the substrate 110 and the second DTI insulation layer 124, and may have a higher refractive index than each of the lens layer 170 and the color filter layer 160.

The grid structure 150 may be formed between adjacent color filters within the color filter layer 160 to prevent optical crosstalk between adjacent color filters. The grid structure 150 may include at least one of an air layer or a metal layer.

The color filter layer 160 may be formed over the anti-reflection layer 140 and may selectively transmit light of a specific wavelength (e.g., red, green, blue, magenta, yellow, cyan, white, etc.). In some implementations, the color filter layer 160 may be omitted or replaced with an infrared (IR) filter when the unit pixel (PX) is a depth pixel for distance measurement.

The lens layer 170 may be formed over the color filter layer 160, and may increase light reception (Rx) efficiency by increasing light gathering power of incident light. The lens layer 170 may include a plurality of microlenses formed to respectively correspond to the unit pixels (PXs). In some other implementations, when the unit pixel (PX) corresponds to a phase detection autofocus (PDAF) pixel, one microlens may be arranged to correspond to two or more unit pixels (PXs).

The pixel transistors 180 for reading out pixel signals based on a driving signal from the row driver 200 may be formed over the second surface of the substrate 110. The pixel transistors 180 may include a transfer transistor configured to transfer photocharges generated by the photoelectric conversion region 112 to a floating diffusion region (FD) in response to a transfer signal; a reset transistor configured to initialize the floating diffusion region (FD) in response to a reset signal; a source follower transistor configured to generate a pixel signal corresponding to the magnitude of the photocharges stored in the floating diffusion region (FD); and a selection transistor configured to output the pixel signal output from the source follower transistor to a column line based on a row selection signal.

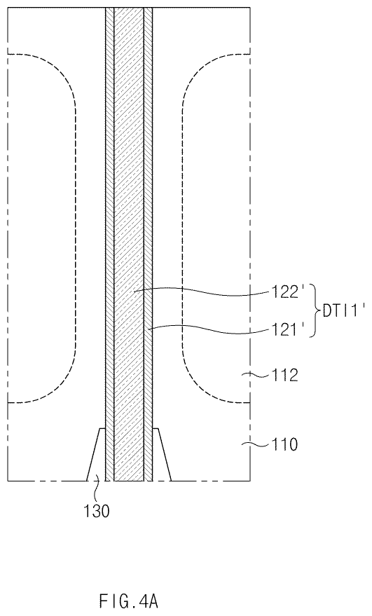

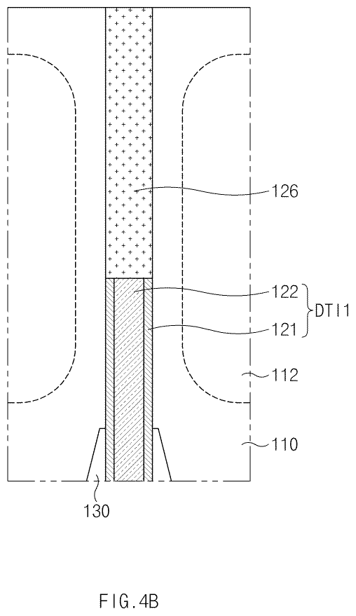

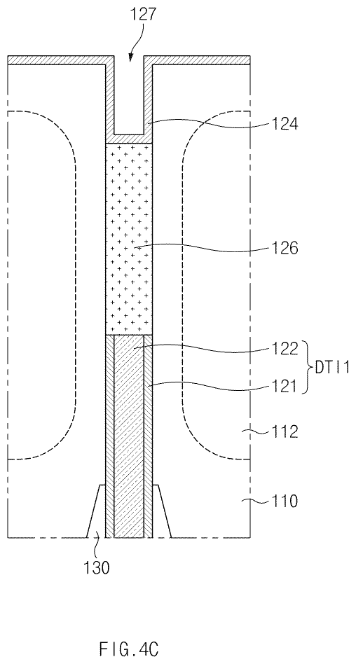

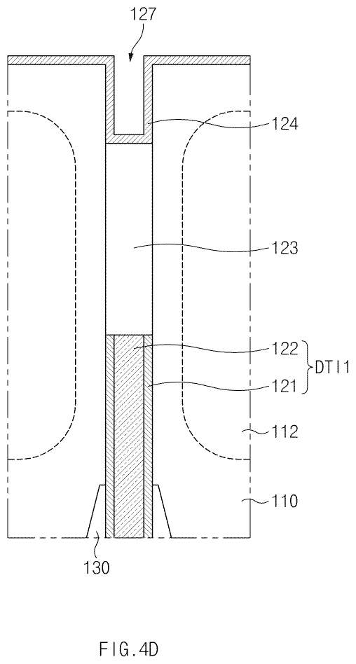

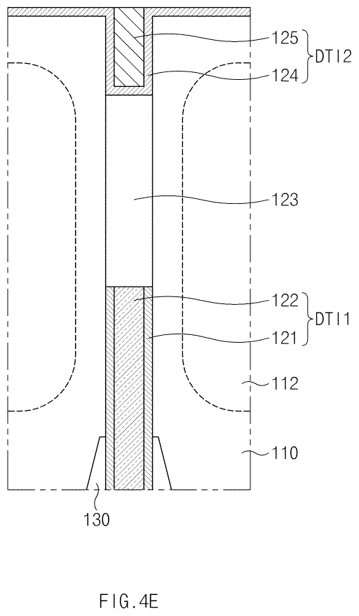

FIGS. 4A to 4E are cross-sectional views illustrating examples of methods for forming the pixel isolation structure of FIG. 3 based on some implementations of the disclosed technology. The following embodiment will hereinafter be mainly described centering upon the pixel isolation structure, and components other than the pixel isolation structure may also be formed by any conventional method.

Referring to FIG. 4A, a first DTI (DTI1′) including a first DTI insulation layer 121′ and a first DTI electrode 122′ may be formed within the substrate 110 in which the photoelectric conversion region 112 and the device isolation structure 130 are formed. The first DTI (DTI1′) may be formed to penetrate the substrate 110. For example, after the first DTI insulation layer 121′ is formed on the side and bottom surfaces of a trench etched from the second surface of the substrate 110 toward the first surface of the substrate 110, the first DTI electrode 122′ may be formed over the first DTI insulation layer 121′ to fill the trench. Subsequently, the first surface of the substrate 110 may be etched through a polishing process until the first DTI electrode 122′ is exposed, thereby forming the first DTI (DTI1′) penetrating the substrate 110.

The first DTI insulation layer 121′ may include an insulation layer such as a silicon oxide layer (SiO₂), a silicon nitride layer (SiN), etc., and the first DTI electrode 122′ may include at least one of a metal, polysilicon, or doped polysilicon. For example, the first DTI electrode 122′ may include doped polysilicon.

Referring to FIG. 4B, the first DTI (DTI1′) may be etched to a predetermined depth from the first surface of the substrate 110, thereby forming the first DTI (DTI1).

Subsequently, a sacrificial layer 126 may be formed to fill the area where the first DTI (DTI1′) was removed. The sacrificial layer 126 may include a spin on carbon (SOC) layer containing carbon.

Referring to FIG. 4C, the sacrificial layer 126 may be etched to a predetermined depth from the first surface of the substrate 110, thereby forming a trench 127. Thereafter, a second DTI insulation layer 124 may be formed on a bottom surface and sidewalls of the trench 127.

The second DTI insulation layer 124 may be formed to extend over the first surface to cover the first surface of the substrate 110. The second DTI insulation layer 124 may include a high-K material including negative fixed charges. For example, the second DTI insulation layer 124 may include a monolayer structure formed of or including either Al₂O₃ or HfO₂, or may include a multilayer structure formed by stacking Al₂O₃ and HfO₂. Alternatively, the second DTI insulation layer 124 may include an ultra-low temperature oxidation (ULTO) layer.

The second DTI insulation layer 124 may be formed to a predetermined thickness through which gas used in a subsequent plasma process and molecules formed by combining the gas with carbon of the sacrificial layer 126 can be easily discharged outside.

Referring to FIG. 4D, a plasma process may be carried out upon the resultant structure of FIG. 4C, such that the sacrificial layer 126 may be removed and the air layer 123 may be formed at the position from which the sacrificial layer 126 is removed. In this case, the plasma process may be carried out using gas (e.g., O₂, N₂, H₂, CO, CO₂, or CH₄) including at least one of oxygen, nitrogen, or hydrogen.

For example, if the O₂ plasma process is carried out upon the resultant structure of FIG. 4C, oxygen radicals (O*) may flow into the sacrificial layer 126 through the second DTI insulation layer 124, and the oxygen radicals (O*) included in the sacrificial layer 126 may be combined with carbons of the sacrificial layer 126, resulting in formation of CO or CO₂. The formed CO or CO₂ may be discharged outside through the second DTI insulation layer 124. As a result, the sacrificial layer 116 can be removed, and the air layer 123 may be formed at the position where the sacrificial layer 116 is removed.

Referring to FIG. 4E, the second DTI electrode 125 may be formed to fill the trench 127 so that the second DTI (DTI2) can be formed over the air layer 123.

The second DTI electrode 125 may include at least one of a metal, polysilicon, or polysilicon doped with impurities. For example, the second DTI electrode 125 may include a metal having a higher conductivity than the first DTI electrode 122.

Thereafter, as shown in FIG. 3, the anti-reflection layer 140, the grid structure 150, the color filter layer 160, and the lens layer 170 may be formed over the second DTI insulation layer 124 and the second DTI electrode 125.

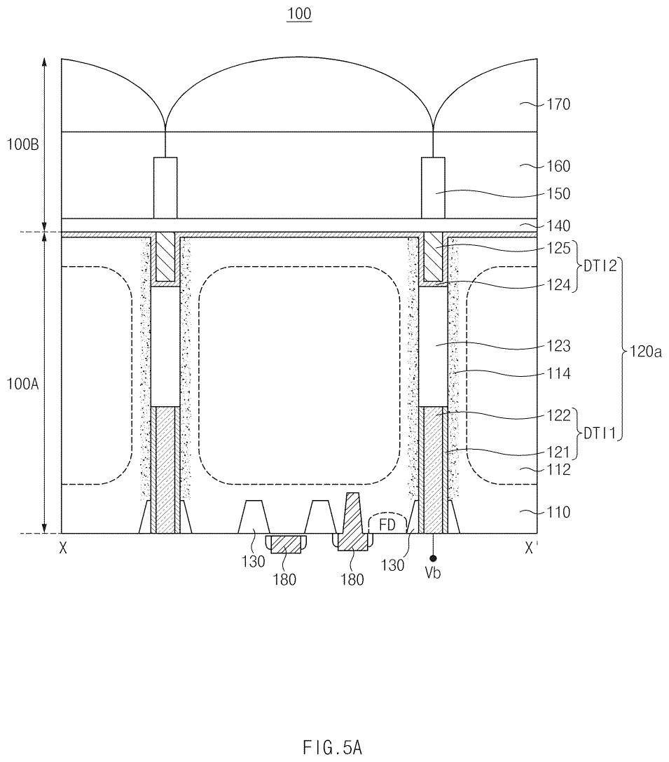

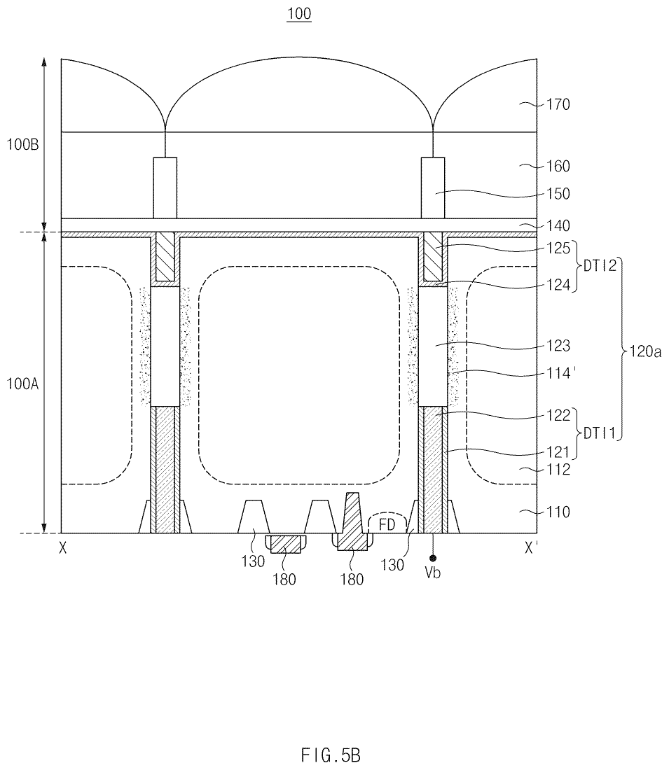

FIGS. 5A and 5B are cross-sectional views illustrating examples of the pixel array taken along the line X-X′ shown in FIG. 2 based on some other implementations of the disclosed technology.

In the embodiment of FIGS. 5A and 5B, the same reference numerals are used for the same components as those of FIG. 3, and as such redundant description thereof will herein be omitted. Hereinafter, the following embodiment of FIGS. 5A and 5B will be described centering upon differences from the embodiment of FIG. 3 to avoid redundant description.

Referring to FIGS. 5A and 5B, the substrate region 100A may include passivation regions (114, 114′) formed on both sides of the air layer 123 of the pixel isolation structure 120a within the substrate 110. Each of the passivation regions (114, 114′) may include P-type impurities at a higher concentration than a well region of the substrate 110.

In the pixel isolation structure 120a, the region where the air layer 123 is formed may have relatively lower dark current characteristics compared to the regions where the DTI electrodes (122, 125) are formed. To compensate for this issue, the passivation region (114, 114′) may be formed on both sides of the pixel isolation structure 120a.

For example, as shown in FIG. 5A, the passivation region 114 may be formed on both sides of the first DTI (DTI1), the air layer 123, and the second DTI (DTI2) of the pixel isolation structure 120a. Alternatively, as shown in FIG. 5B, the passivation region 114′ may be selectively formed on only both sides of the air layer 123 from among the first DTI (DTI1), the air layer 123, and the second DTI (DTI2).

The passivation region 114 may be formed by implanting high concentration P-type impurities into the sidewall of the trench before the first DTI (DTI1) is formed in the structure of FIG. 4A. The passivation region 114′ may be formed by implanting high concentration P-type impurities into the sidewall of the trench before the sacrificial layer 126 is formed in the structure of FIG. 4B.

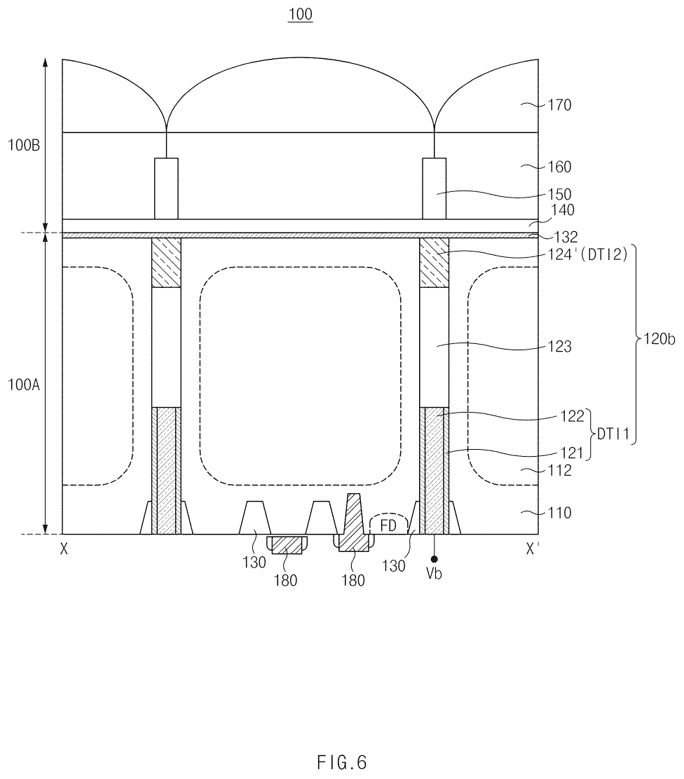

FIG. 6 is a cross-sectional view illustrating an example of the pixel array taken along the line X-X′ shown in FIG. 2 based on some other implementations of the disclosed technology.

In the embodiment of FIG. 6, the same reference numerals are used for the same components as those of FIG. 3, and as such redundant description thereof will herein be omitted. Hereinafter, the following embodiment of FIG. 6 will be described centering upon differences from the embodiment of FIG. 3 to avoid redundant description.

Referring to FIG. 6, the pixel isolation structure 120b may include a structure in which a second DTI insulation layer 124′ is gap-filled over the air layer 123. For example, the pixel isolation structure 120b may be formed so that the second DTI (DTI2) formed at the first surface includes only a high-K material without including an electrode material.

As is apparent from the above description, the image sensing device can improve light efficiency while improving dark current characteristics.

The embodiments of the disclosed technology may provide a variety of effects capable of being directly or indirectly recognized through the above-mentioned patent document.

While various embodiments have been described above, it will be understood to those skilled in the art that the embodiments described are examples only. Accordingly, variations and improvements of the described embodiments for the image sensing devices described herein can be made. For example, some implementations as discussed above can be presented in combination as an embodiment. In addition, other embodiments can be devised based on what is described and/or illustrated in this patent document.

What is claimed is:

1. An image sensing device comprising:
a semiconductor substrate including a first surface and a second surface facing or opposite to the first surface;
photoelectric conversion regions supported by the semiconductor substrate and configured to generate photocharges in response to incident light received through the first surface; and
a pixel isolation structure disposed between adjacent photoelectric conversion regions in the semiconductor substrate and configured to have a conductive material,
wherein the pixel isolation structure includes:
a first deep trench isolation (DTI) electrode extending from the second surface toward the first surface; and
a second DTI electrode extending from the first surface toward the second surface and disposed apart from the first deep trench isolation (DTI) electrode to define a space for an air layer including air.

2. The image sensing device according to claim 1, wherein:
the first DTI electrode and the second DTI electrode are configured to include different conductive materials from each other.

3. The image sensing device according to claim 2, wherein:
the first DTI electrode includes doped polysilicon; and
the second DTI electrode includes a metal.

4. The image sensing device according to claim 1, wherein:
the first DTI electrode and the second DTI electrode are configured to have different lengths from each other.

5. The image sensing device according to claim 1, further comprising:
a first DTI insulation layer disposed between the first DTI electrode and the semiconductor substrate; and
a second DTI insulation layer disposed between the second DTI electrode and the semiconductor substrate and between the second DTI electrode and the air layer.

6. The image sensing device according to claim 5, wherein the second DTI insulation layer includes:
a structure in which Al₂O₃ and HfO₂ are stacked.

7. The image sensing device according to claim 5, wherein:
the second DTI insulation layer is configured to extend over the first surface to cover the first surface.

8. The image sensing device according to claim 1, further comprising:
a passivation region disposed at two sides of the pixel isolation structure within the semiconductor substrate.

9. The image sensing device according to claim 8, wherein:
the passivation region is disposed at two sides of the first DTI electrode, the second DTI electrode, and the air layer.

10. The image sensing device according to claim 8, wherein:
the passivation region is disposed only at sides of the air layer from among the first DTI electrode, the second DTI electrode, and the air layer.

11. An image sensing device comprising:
a semiconductor substrate including photoelectric conversion regions configured to generate photocharges in response to incident light; and
a pixel isolation structure disposed between the photoelectric conversion regions within the semiconductor substrate,
wherein the pixel isolation structure includes:
a first deep trench isolation (DTI);
a second deep trench isolation (DTI) disposed to be isolated from the first DTI by an air layer including air.

12. The image sensing device according to claim 11, wherein the first DTI includes:
a first deep trench isolation (DTI) electrode configured to have a conductive material; and
a first deep trench isolation (DTI) insulation layer disposed between the first DTI electrode and the semiconductor substrate.

13. The image sensing device according to claim 11, wherein the second DTI includes:
a second deep trench isolation (DTI) electrode configured to have a conductive material; and
a second deep trench isolation (DTI) insulation layer disposed between the second DTI electrode and the semiconductor substrate and between the second DTI electrode and the air layer.

14. The image sensing device according to claim 11, wherein:
the first DTI and the second DTI are configured to include different conductive materials from each other.

15. The image sensing device according to claim 13, wherein:
the second DTI insulation layer is configured to include a high-K material.

16. The image sensing device according to claim 11, wherein:
the second DTI is configured to include a high-K material only without including any other material.

17. The image sensing device according to claim 11, further comprising:
a passivation region disposed at two sides of the pixel isolation structure within the semiconductor substrate.
